(19) United States
(12) Patent Application Publication
(10) Pub. No.: US 2008/0001538 A1
(43) Pub. Date: Jan. 3, 2008

(54) LED DEVICE HAVING IMPROVED LIGHT OUTPUT

(76) Inventor: Ronald S. Cok, Rochester, NY (US)

Correspondence Address: Frank Pincelli;Patent Legal Staff, Eastman Kodak Company, 343 State Street, Rochester, NY, 14650-2201, US

(21) Appl. No.: 11/679,307

(22) Filed: Feb. 27, 2007

Related U.S. Application Data
(63) Continuation-in-part of application No. 11/427,603, filed on Jun. 29, 2006.

(51) Int. Cl. H05B 33/00; H05B 33/10

(52) U.S. Cl. 313/506; 445/58

(57) ABSTRACT

An light-emitting diode (LED) device, comprising: a transparent substrate; a transparent thin-film transistor located over the substrate; a light-emitting element formed over the transparent thin-film transistor, wherein the light-emitting element comprises a first transparent extensive electrode formed at least partially over a portion of the transparent thin-film transistor, a layer of light-emitting material, and a second reflective electrode formed over the layer of light-emitting material; a low-index layer formed between the first transparent extensive electrode and the thin-film transistor; and a light-scattering layer formed between the low-index layer and the second reflective electrode, or formed as part of the second reflective electrode.

### CROSS-REFERENCE TO RELATED APPLICATIONS

This is a Continuation-In-Part of U.S. application Ser. No. 11/427,603, filed 29 Jun. 2006, entitled “OLED DEVICE HAVING IMPROVED LIGHT OUTPUT” by Ronald S. Cok.

### FIELD OF THE INVENTION

The present invention relates to light-emitting diode (LED) devices, and more particularly, to LED device structures for improving light output and device lifetime.

### BACKGROUND OF THE INVENTION

Light-emitting diodes (LEDs) are a promising technology for flat-panel displays and area illumination lamps. The technology relies upon thin-film layers of materials coated upon a substrate. LED devices can have several formats, for example organic light-emitting diodes, crystalline light-emitting diodes formed on silicon substrates, and quantum dot light-emitting diodes formed in layers with many quantum dot emitters.

Small-molecule organic devices are disclosed in U.S. Pat. No. 4,476,292, issued Oct. 9, 1984 by Ham et al., and polymer-OLED devices are disclosed in U.S. Pat. No. 5,247,190, issued Sep. 21, 1993 by Friend et al. Either type of OLED device may include, in sequence, an anode, an organic EL element, and a cathode. The organic EL element disposed between the anode and the cathode commonly includes an organic hole-transporting layer (HTL), a light-emissive layer (LEL) and an organic electron-transporting layer (ETL). Holes and electrons recombine and emit light in the LEL layer. Tang et al. (Applied Physics Letter 51, 913 (1987), Journal of Applied Physics, 65, 3610 (1989), and U.S. Pat. No. 4,769,292) demonstrated highly efficient OLEDs using such a layer structure. Since then, numerous OLEDs with alternative layer structures, including polymeric materials, have been disclosed and device performance has been improved.

Semiconductor light emitting diode (LED) devices, which are primarily inorganic, have been made since the early 1960's and currently are manufactured for usage in a wide range of consumer and commercial applications. The layers comprising the LEDs are based on crystalline semiconductor materials. These crystalline-based inorganic LEDs have the advantages of high brightness, long lifetimes, and good environmental stability. The crystalline semiconductor layers that provide these advantages also have a number of disadvantages. The dominant ones have high manufacturing costs; difficulty in combining multi-color output from the same chip; efficiency of light output; and the need for high-cost rigid substrates. However, in comparison to OLEDs, crystalline-based inorganic LEDs have improved brightness, longer lifetimes, and do not require expensive encapsulation for device operation.

Quantum dots are light-emitting nano-sized semiconductor crystals. Adding quantum dots to the emitter layers could enhance the color gamut of the device; red, green, and blue emission could be obtained by simply varying the quantum dot particle size; and the manufacturing cost could be reduced. Because of problems such as aggregation of the quantum dots in the emitter layer, the efficiency of these devices was rather low in comparison with typical OLED devices. The efficiency was even poorer when a neat film of quantum dots was used as the emitter layer (Hikmet et al., Journal of Applied Physics 93, 3509 (2003)). The poor efficiency was attributed to the insulating nature of the quantum dot layer. Later the efficiency was boosted (to ˜1.5 cd/A) upon depositing a mono-layer film of quantum dots between organic hole and electron transport layers (Coe et al., Nature 420, 800 (2002)). It was stated that luminescence from the quantum dots occurred mainly as a result of Forster energy transfer from excitons on the organic molecules (electron-hole recombination occurs on the organic molecules). Regardless of any future improvements in efficiency, these hybrid devices still suffer from all of the drawbacks associated with pure OLED devices.

Recently, a mainly all-inorganic LED was constructed (Mueller et al., Nano Letters 5, 1039 (2005)) by sandwiching a monolayer thick core/shell CdSe/ZnS quantum dot layer between vacuum deposited inorganic n- and p-GaN layers. The resulting device had a poor external quantum efficiency of 0.001 to 0.01%. Part of that problem could be associated with the organic ligands of trioctylphosphine oxide (TOPO) and trioctylphosphine (TOP) that were reported to be present post growth. These organic ligands are insulators and would result in poor electron and hole injection onto the quantum dots. In addition, the remainder of the structure is costly to manufacture, due to the usage of electron and hole semiconducting layers grown by high-vacuum techniques, and the usage of sapphire substrates.

As described in co-pending, commonly assigned U.S. application Ser. No. 11/226,622, filed Sep. 14, 2005 by Kahen, which is hereby incorporated by reference in its entirety, additional conducting particles may be provided with the quantum dots in a layer to enhance the conductivity of the light-emitting layer.

Light-emitting diode structures may be employed to form flat-panel displays. Likewise, colored-light or white-light lighting applications are of interest. Different materials may be employed to emit different colors and the materials may be patterned over a surface to form full-color pixels. In various embodiments, the quantum dot LEDs may be electronically or photonically stimulated and may be mixed or blended with a light-emitting organic host material and located between two electrodes.

Referring to FIG. 2, a prior-art structure employing electronic stimulation uses a substrate 10 on which is formed a first electrode 12, a light-emissive layer 14, and a second electrode 16. Upon the application of a current from the electrodes, electrons and holes injected into the matrix create excitors that are transferred to the quantum dots for recombination, thereby stimulating the quantum dots to produce light. Such a design is described in WO 2005/055330, published 16 Jun. 2005 by Hikmet et al., entitled “Electroluminescent Device.” P-type and/or an n-type transport, charge injection, and/or charge blocking layers may be optionally employed to improve the efficiency of the device. Typically, one electrode will be reflective (e.g. second electrode 16) while the other may be transparent (e.g. first electrode 12). No particular order is necessitated for electrodes 12 and 16, although they are referenced throughout in this document as first and second, respectively.

A typical LED device uses a glass substrate, a transparent conducting anode such as indium-tin-oxide (ITO), a stack of charge-control and light-emitting layers, and a reflective cathode layer. Light generated from the device is emitted through the glass substrate, and this is commonly referred to as a bottom-emitting device. Alternatively, an LED device can include a substrate, a reflective anode, a stack of charge-control and light-emitting layers, and a top transparent cathode layer. Light generated from this alternative device is emitted through the top transparent electrode, and this is commonly referred to as a top-emitting device. In general, bottom-emitting LED devices are easier to manufacture because the transparent electrode (e.g. ITO) employed in a top-emitting device may be difficult to deposit over the charge-control and light-emitting layers without damaging them and suffers from limited conductivity. In contrast, the evaporation of a reflective metal electrode has proved to be relatively robust and conductive. However, active-matrix bottom-emitting LED devices suffer from a reduced light-emitting area (aperture ratio), since a significant proportion (over 70%) of the substrate area can be taken up by the active-matrix components, bus lines, etc. Since some LED materials degrade in proportion to the current density passed through them, a reduced aperture ratio will increase the current density through the layers at a constant brightness, thereby significantly reducing the LED device's lifetime. Top-emitting LED devices can employ an increased aperture ratio, since light emitted from the device passes through the cover, rather than the substrate. Active-matrix devices formed on the substrate can be covered with an insulating layer and a reflective electrode formed over the active-matrix components, thereby increasing the light-emitting area. Active-matrix components, typically thin-film transistors are formed on the substrate using photolithographic processes. Such processes cannot be performed over some charge-control and light-emitting layers, since the processes will destroy the layers.

Displays that emit light from both sides of the device are also known. US Publication 2006/0038752 by Winters, for example, describes an emissive display device for producing images that has a plurality of first pixels each having an emissive area wherein the plurality of first pixels define a first viewing region, wherein each first pixel produces light emission which is visible when viewing the first side of the display device; and a plurality of second pixels each having an emissive area and wherein the plurality of second pixels define a second viewing region, wherein each second pixel produces light emission which is visible when viewing the second side of the display device, wherein at least a portion of the plurality of first and second pixels are interleaved.

Transparent inorganic and organic materials from which thin-film transistors can be made are also known. For example inorganic doped metal oxides such as aluminum zinc oxide can be employed as well as organic materials such as pentacene. Using these materials, completely transparent displays may be constructed. For example, in “Towards See-Through Displays: Fully Transparent Thin-Film Transistors Driving Transparent Organic Light-Emitting Diodes,” in Advanced Materials, 2006, 18(6), 738-741 published by Wiley-VCH Verlag GmbH & Co., entirely transparent pixels composed of monolithically integrated transparent organic light-emitting diodes driven by transparent thin-film transistors are presented. With an average transmittance of more than 70% in the visible part of the spectrum (400-750 nm), the presented active pixels may enable the realization of practically transparent active-matrix displays. However, in many applications a transparent display is not desired while an improved display emitting light from one side is desired.

US Publication 2004/0155846 entitled “Transparent Active-Matrix Display” by Hoffman et al., describes the use of transparent active pixel elements and transparent electrical connections. While the disclosure is primarily directed towards use of such transparent pixel elements in display devices that emit light from both sides of the device, it is disclosed that transparent thin-film transistors may be employed with a transparent bottom electrode together with a reflective back (top) electrode formed over the otherwise transparent pixel elements. Such embodiment may provide a greater aperture ratio in a bottom-emitter OLED device, compared to bottom-emitting devices employing conventional non-transparent thin-film transistors. Referring to FIG. 2, a bottom-emitting active-matrix LED device as may be suggested by the prior-art has a transparent substrate 10, a layer of transparent thin-film electronic components 30 formed over the substrate 10. Planarization insulating layer 32 protects the layer of thin-film electronic components 30. A transparent electrode 12 is formed over the substrate 10, planarization insulating layer 32, and at least partially over the layer of thin-film electronic components 30. A second planarization insulating layer 34 is formed between the transparent electrodes 12 to prevent shorts between them. One or more layers 14 of material, one of which is light-emitting, is formed over the transparent electrodes 12 and a common, reflective electrode 16 is formed over the layers 14 of material. To simplify the manufacturing process, the layers 14 and reflective electrode 16 are typically formed over the entire device, even though only those portions 60 of the device corresponding to the extent of the transparent electrode 12 will emit light 64. The transparent electrodes 12 may be formed adjacent to and over the active-matrix components 30 because the components 30 are transparent and light 64 emitted from the portion 60 can pass through the active-matrix components 30 and out of the LED device. Because the electrodes 12 and 16 extend over the transparent active-matrix thin-film electronic components 30, the portions 60 of the LED device that emits light 64 may be much larger than if the active-matrix components 30 were not transparent, thereby improving the lifetime of the LED device. An encapsulating cover 20 may be located over the transparent electrode 12 and adhered to the substrate 10 to protect the LED device.

Typical indices of refraction for the charge-control and light-emitting layers range from 1.6 to 1.7 for organic materials and well over 2.0 for inorganic layers and the refractive index of commonly used transparent conductive metal oxides such as indium tin oxide (ITO) is often greater than 1.8 and often near 2.0. Hence, light emitted in an layer at a high angle with respect to the normal can totally internally reflect and be trapped in the high optical index materials of the layers and transparent electrodes, and not be emitted from the device, thereby reducing the efficiency of the LED device. Hence, light may be trapped in the high-index layers 10, 30, 12, 14, 32, and 34.

A variety of techniques have been proposed to improve the out-coupling of light from thin-film, light-emitting devices. For example, diffraction gratings have been proposed to control the attributes of light emission from thin polymer films by inducing Bragg scattering of light that is guided laterally through the emissive layers; see “Modification Of Polymer Light Emission By Lateral Microstructure” by Safonov et al., Synthetic Metals 116, 2001, pp. 145-148, and “Bragg Scattering From Periodically Microstructured Light Emitting Diodes” by Lupton et al., Applied Physics Letters, Vol. 77, No. 21, Nov. 20, 2000, pp. 3340-3342. Brightness enhancement films having diffractive properties and surface and volume diffusers are described in WO0237568 A1 entitled “Brightness and Contrast Enhancement of Direct View Emissive Displays” by Chou et al., published May 10, 2002. The use of micro-cavity techniques is also known; for example, see “Sharply Directed Emission In Organic Electroluminescent Diodes With An Optical-Microcavity Structure” by Tsutsui et al., Applied Physics Letters 65, No. 15, Oct. 10, 1994, pp. 1868-1870. However, none of these approaches cause all, or nearly all, of the light produced to be emitted from the device. Moreover, such diffractive techniques cause a significant frequency dependence on the angle of emission so that the color of the light emitted from the device changes with the viewer's perspective.

Reflective structures surrounding a light-emitting area or pixel are referenced in U.S. Pat. No. 5,834,893 issued Nov. 10, 1998 to Bulovic et al. and describe the use of angled or slanted reflective walls at the edge of each pixel. Similarly, Forrest et al. describe pixels with slanted walls in U.S. Pat. No. 6,091,195 issued Jul. 18, 2000. These approaches use reflectors located at the edges of the light-emitting areas. However, considerable light is still lost through absorption of the light as it travels laterally through the layers parallel to the substrate within a single pixel or light emitting area.

Scattering techniques are also known. Chou (International Publication Number WO 02/37580) and Liu et al. (U.S. Patent Application Publication No. 2001/0026124) taught the use of a volume or surface scattering layer to improve light extraction. The scattering layer is applied next to the organic layers or on the outside surface of the glass substrate and has an optical index that matches these layers. Light emitted from the OLED device at higher than critical angle that would have otherwise been trapped can penetrate into the scattering layer and be scattered out of the device. The efficiency of the OLED device is thereby improved but still has deficiencies as explained below.

U.S. Pat. No. 6,787,796 entitled “Organic Electroluminescent Display Device And Method Of Manufacturing The Same” by Do et al issued Sep. 9, 2004, describes an organic electroluminescent (EL) display device and a method of manufacturing the same. The organic EL device includes a substrate layer, a first electrode layer formed on the substrate layer, an organic layer formed on the first electrode layer, and a second electrode layer formed on the organic layer, wherein a light loss preventing layer having different refractive index areas is formed between layers of the organic EL device having a large difference in refractive index among the respective layers. U.S. Publication No. 2004/0217702 entitled “Light Extracting Designs For Organic Light Emitting Diodes” by Garner et al., similarly discloses use of microstructures to provide internal refractive index variations or internal or surface physical variations that function to perturb the propagation of internal waveguide modes within an OLED. When employed in a top-emitter embodiment, the use of an index-matched polymer adjacent the encapsulating cover is disclosed. US Publication 2005/0142379 entitled “Electroluminescence Device, Planar Light Source And Display Using The Same” describes an organic electroluminescence device including an organic layer comprising an emissive layer; a pair of electrodes comprising an anode and a cathode, and sandwiching the organic layer, wherein at least one of the electrodes is transparent; a transparent layer provided adjacent to a light extracting surface of the transparent electrode; and a region substantially disturbing reflection and retraction angle of light provided adjacent to a light extracting surface of the transparent layer or in an interior of the transparent layer, wherein the transparent layer has a refractive index substantially equal to or more than the refractive index of the emissive layer.

Light-scattering layers used externally to an OLED device are described in U.S. Publication 2005/0018431 entitled “Organic Electroluminescent Devices Having Improved Light Extraction” by Shiang and U.S. Pat. No. 5,955,837 entitled “System With An Active Layer Of A Medium Having Light-Scattering Properties For Flat-Panel Display Devices” by Horikx, et al. These disclosures describe and define properties of scattering layers located on a substrate in detail. Likewise, U.S. Pat. No. 6,777,871 entitled “Organic ElectroLuminescent Devices with Enhanced Light Extraction” by Duggal et al., describes the use of an output coupler comprising a composite layer having specific refractive indices and scattering properties. While useful for extracting light, this approach will only extract light that propagates in the substrate, and will not extract light that propagates through the organic layers and electrodes. Moreover, trapped light may propagate a considerable distance horizontally through the cover, substrate, or organic layers before being scattered out of the device, thereby reducing the sharpness of the device in pixilated applications such as displays.

U.S. Patent Application Publication No. 2004/0061136 entitled “Organic Light Emitting Device Having Enhanced Light Extraction Efficiency” by Tyan et al., describes an enhanced, light-extraction OLED device that includes a light-scattering layer. In certain embodiments, a low-index isolation layer (having an optical index substantially lower than that of the organic electroluminescent element) is employed adjacent to a reflective layer in combination with the light-scattering layer to prevent low-angle light from striking the reflective layer, and thereby minimize absorption losses due to multiple reflections from the reflective layer. The particular arrangements, however, may still result in reduced sharpness of the device.

EP Patent 1 603 367, by Handa et al., entitled “Electroluminescence Device” discloses an electroluminescent device successively comprising a cathode, an electroluminescent layer, a transparent electrode layer, an evanescent light-scattering layer comprising a matrix composed of a low-refractive material containing light-scattering particles, and a transparent sheet/plate. EP1603367 A1 also includes an internal low-refractive layer to inhibit the propagation of light in a cover or substrate.

Co-pending, commonly assigned U.S. Ser. No. 11/065,082, filed Feb. 24, 2005, the disclosure of which is incorporated by reference herein, describes the use of a transparent low-index layer having a refractive index lower than the refractive index of the encapsulating cover or substrate through which light is emitted and lower than the organic layers to enhance the sharpness of an OLED device having a scattering element. Both bottom-emitting and top-emitting embodiments are described. US 2005/0194896 describes a nano-structure layer for extracting radiated light from a light-emitting device together with a gap having a refractive index lower than an average refractive index of the emissive layer and nano-structure layer. Co-pending, commonly assigned U.S. Ser. No. 11/387,492, filed Mar. 23, 2006, the disclosure of which is incorporated by reference herein, describes processes for forming optical isolation layers having refractive index close to one in bottom-emitting devices, such as cavities filled with a gas, formed between a substrate and an EL element. However, the question of improving the lifetimes of OLED devices when formed in such top- and bottom-emitting structures themselves is not addressed. While transparent materials may be employed, because the layers 30, 32, and 34 are relatively thick in comparison to the light-emitting layer, light can travel some distance in these layers, possibly between light-emitting elements, and may thereby degrade the sharpness of the device. Moreover, the presence of light in the thin-film transistors 30 may change the transistors' operation and, although the transistors are relatively transparent, they may not be completely transparent or colorless, thereby changing the amount and color of light emitted, especially if employed in combination with a scattering layer, since application of scattering techniques may cause light to pass repeatedly through any layers between a reflector and the scattering layer.

There is a need therefore for an improved light-emitting diode device structure that avoids the problems noted above and improves the lifetime, efficiency, and sharpness of the device.

### SUMMARY OF THE INVENTION

In accordance with one embodiment, the invention is directed towards a light-emitting diode (LED) device, comprising:

a transparent substrate;

one-or-more transparent thin-film transistors located over the substrate;

one or more light-emitting elements formed over the transparent thin-film transistors, wherein each light-emitting element comprises:
a first transparent extensive electrode formed at least partially over at least a portion of the one-or-more transparent thin-film transistors;
at least one layer of light-emitting material formed over the first transparent extensive electrode; and
a second reflective electrode formed over the at least one layer of light-emitting material;

a low-index layer formed between the first transparent extensive electrode and the one-or-more thin-film transistors, the low-index layer having an optical index lower than that of the layer of light-emitting material, the transparent thin-film transistors, and the transparent substrate; and

a light-scattering layer formed between the low-index layer and the second reflective electrode, or formed as part of the second reflective electrode.

### ADVANTAGES

The present invention has the advantage that it increases the lifetime, brightness, and sharpness of an LED device.

### BRIEF DESCRIPTION OF THE DRAWINGS

FIG. 1 illustrates a cross section of a bottom-emitter LED device having a scattering layer and low-index gap according to one embodiment of the present invention;

FIG. 2 illustrates a bottom-emitting LED as suggested by the prior art;

FIG. 3 illustrates a cross section of a bottom-emitter LED device having a scattering layer and a low-index gap according to an alternative embodiment of the present invention;

FIG. 4 illustrates a cross section of a bottom-emitter LED device having a scattering layer and a low-index gap according to a further embodiment of the present invention;

FIG. 5 illustrates a cross section of an LED device having charge-control layers according to a further embodiment of the present invention;

FIG. 6 is an illustrative schematic of a quantum dot according to yet another embodiment of the present invention; and

FIG. 7 illustrates a light-emitting layer comprising quantum dots and non-light-emissive particles according to another embodiment of the present invention.

Notably, the figures are not to scale, since the individual layers are too thin and the thickness differences of various layers too great to permit depiction to scale.

### DETAILED DESCRIPTION OF THE INVENTION

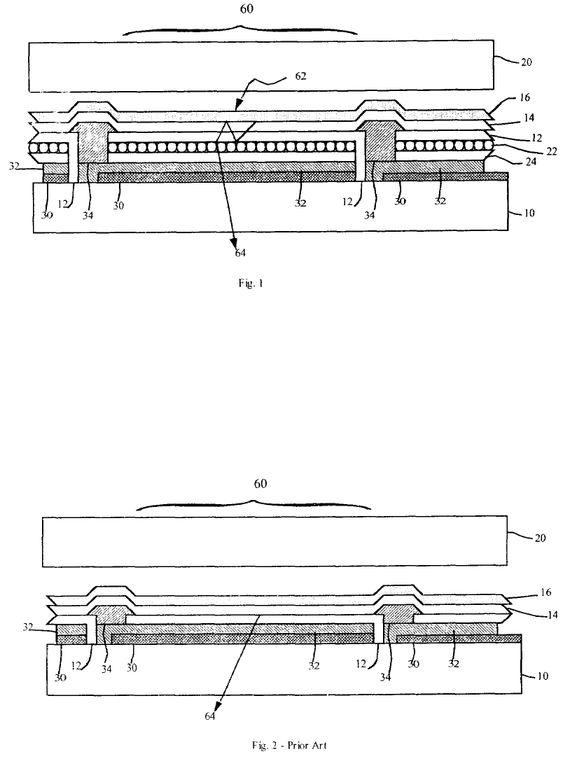

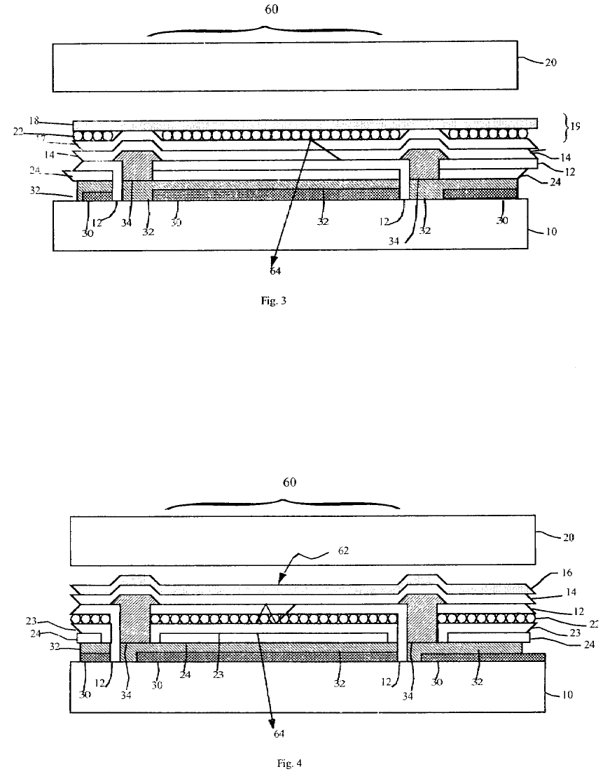

Referring to FIG. 1, in accordance with one embodiment of the present invention, a light-emitting diode (LED) device, comprises a transparent substrate 10, one-or-more transparent thin-film transistors 30 located over the substrate 10; one or more light-emitting elements 62 formed over the transparent thin-film transistors 30, wherein each light-emitting element 62 comprises a first transparent extensive electrode 12 formed at least partially over at least a portion of the one-or-more transparent thin-film transistors 30, at least one layer 14 of light-emitting material formed over the first transparent extensive electrode, and a second reflective electrode 16 formed over the at least one layer 14 of light-emitting material; a low-index layer 24 formed between the first transparent extensive electrode 12 and the one-or-more thin-film transistors 30, the low-index layer 24 having an optical index lower than that of the layer 14 of light-emitting material, the transparent thin-film transistors 30, and the transparent substrate 10; and a light-scattering layer 22 formed between the low-index layer 24 and the second reflective electrode 16. In the particular embodiment of FIG. 1, the scattering layer 22 is formed between the low-index layer 24 and the first transparent extensive electrode 12. In alternative embodiments as discussed below, the scattering layer 22 may be formed as part of the second reflective electrode 16.

In operation an active-matrix LED device such as that depicted in FIG. 1 employs transparent thin-film electronic components including transparent thin-film transistors 30 to provide a current through the patterned transparent extensive electrode 12, light-emitting layer 14, and a reflective, unpatterned electrode 16. Planarization insulating layers 32 and insulating layers 34 protect the electronic components and prevent patterned transparent extensive electrodes 12 from shorting to each other and thereby form light-emissive areas 60. When a current is provided between the electrodes, one or more of the layers 14 emit light. The light is emitted in all directions so that some light will be emitted through the transparent extensive electrode 12, encounter the scattering layer 22, and be scattered into the low-index layer 24. Because the low-index layer 24 has a lower optical index than the transparent substrate 10 and transparent thin-film components 30, any light that enters the low-index layer 24 will also pass through the thin-film transistors 30 and transparent substrate 10. Light that is not scattered into the low-index layer 24 will eventually be reflected from the reflective electrode 16 and be re-scattered by the scattering layer 22 until the light eventually passes into the low-index layer 24 and exits the device through the substrate 10.

Referring to FIG. 3 in an alternative embodiment, a multi-layer reflective electrode 19 is formed over the light-emitting layers 14. The multi-layer reflective electrode 19 comprises a transparent conductive layer 17, scattering layer 22, and a reflective layer 18. The transparent conductive layer 17 may comprise a conductive metal oxide, for example indium tin oxide or aluminum zinc oxide. The reflective layer 18 may also be conductive and comprise, for example, aluminum, silver, magnesium or various metallic alloys, and assist in the conduction of current to the transparent conductive layer 17. In this case, the scattering layer 22 may not be co-extensive with the transparent conductive layer 17 so that the reflective layer 18 may contact the transparent conductive layer 17. Preferably, such contacts are made between the light-emitting areas 60 of the LED device and are defined by the patterning of the transparent extensive electrode 12. Scattering layer 22 itself may also comprise conductive elements. In a further embodiment, scattering layer 22 may comprise a rough light-scattering surface of a reflective electrode 16 or 19.

The scattering layer 22 may employ a variety of materials. For example, particles of SiNₓ (x>1), Si₃N₄, TiO₂, MgO, ZnO may be employed. Titanium dioxide (e.g., refractive index of 2.5 to 3) particles may be particularly preferred. Shapes of refractive particles may be variable or random, cylindrical, rectangular, or spherical, but it is understood that the shape is not limited thereto. Use of variable shaped particles is particularly preferred to enhance random scattering of light over wide wavelength and angle distributions. A large difference in refractive indices between materials in the scattering layer 22 and the low-index gap is generally desired, and may be, for example, from 0.3 to 3. It is generally preferred to avoid diffractive effects in the scattering layer. Such effects may be avoided, for example, by locating features randomly or by ensuring that the sizes or distribution of the refractive elements are not the same as the wavelength of the color of light emitted by the device from the light-emitting area. It is preferred that the total diffuse transmittance of the scattering layer coated on a glass support should be high (preferably greater than 80%) and the absorption of the scattering layer should be as low as possible (preferably less than 5%, and ideally 0%).

Low index layer 24 preferably comprises an optical isolation cavity such as may be formed as described in co-pending commonly assigned U.S. Ser. No. 11/387,492 incorporated by reference above. Such cavity may be filled with a gas, for example air or an inert gas such as nitrogen, argon or helium. This gas may be at reduced pressure compared to atmospheric pressure by forming under vacuum conditions. Preferably, the optical isolation cavity is at least one micron thick, and more preferably at least two microns thick. Such an optical isolation cavity may be formed by depositing a sacrificial layer over for example, the insulating and planarizing layer 32. A second layer 23 (as shown in FIG. 4), or transparent electrode 12 itself, may then be formed over the sacrificial layer, the second layer 23 or electrode 12 having openings exposing portions of the sacrificial layer. An etchant may then be employed to etch the materials of the sacrificial layer away, leaving a cavity beneath the second layer 23 or electrode 12 forming the low-index layer 24 in the form of an optical isolation cavity. Further layers, for example the scattering layer 22 or transparent electrode 12 may be formed over the second layer 23. The second layer 23 or electrode 12 may be supported over the low-index layer 24 isolation cavity by walls adjacent to the light emitting areas 60 or by pillars of support material formed in the light-emissive area 60. The walls or pillars may comprise the same materials as the second layer 23 and be formed in a common patterning step. In such an embodiment, the sacrificial layer may be formed only in the light-emissive area 60.

Materials and etchants known in the photolithographic industry may be employed to form the sacrificial layer and/or second layer 23. In particular, the micro-electromechanical systems (MEMS) art describes useful techniques, as described in commonly assigned U.S. Pat. No. 6,238,581 entitled “Process for manufacturing an electromechanical grating device”. This disclosure describes a method for manufacturing a mechanical grating device comprising the steps of: providing a spacer layer on top of a protective layer which covers a substrate; etching a channel entirely through the spacer layer; depositing a sacrificial layer at least as thick as the spacer layer; rendering the deposited sacrificial layer optically coplanar by chemical mechanical polishing; providing a tensile ribbon layer completely covering the area of the channel; providing a conductive layer patterned in the form of a grating; transferring the conductive layer pattern to the ribbon layer and etching entirely through the ribbon layer; and removing entirely the sacrificial layer from the channel. With respect to the present invention, such a process can be simplified since the requirement for chemical mechanical polishing and the grating structure are unnecessary. Likewise, U.S. Pat. No. 6,307,663 and, in particular, U.S. Pat. No. 6,663,788 describe further devices having cavities and methods for forming cavities useful in the present invention. For example, the sacrificial layer may comprise a silicon, including a polysilicon or a silicon oxide, or an organic polymer, including a polyamide. The second layer may comprise a silicon nitride, a silicon oxide, or a metal oxide. The choice of materials will depend greatly on the choice of etchants, for example XeF₂ can etch silicon, such as polysilicon. Suitable cavities may be formed by employing a sacrificial layer of polysilicon formed over a silicon dioxide layer with a second layer of silicon nitride having photolithographically patterned openings exposing portions of the first sacrificial layer and then etching away the polysilicon sacrificial layer using XeF₂ gas. In an alternative embodiment, the sacrificial layer may be silicon dioxide covered with indium tin oxide (ITO) and hydrofluoric acid employed to etch out the silicon dioxide sacrificial layer. In this embodiment, the ITO layer may serve as a transparent electrode 12, thus eliminating the need for a separate second layer 23 and thereby may reduce materials costs, processing steps, and improve optical performance by avoiding light absorption in a separate second layer 23. Such an embodiment may be most useful in combination with the configuration of FIG. 3 that employs a scattering layer 22 adjacent to the reflective layer 18.

The present invention may be employed with either rigid (e.g. glass) or flexible (e.g. polymer) substrates. In some embodiments, the substrate 10 may comprise glass or plastic with typical refractive indices of between 1.4 and 1.6. Reflective second electrode 16 is preferably made of metal (for example aluminum, silver, or magnesium) or metal alloys. Transparent electrode 12 may be made of transparent conductive materials, for example indium tin oxide (ITO) or other metal oxides. The light-emitting layers 14 may comprise organic materials, for example, hole-injection, hole-transport, light-emitting, electron-injection, and/or electron-transport layers. Such organic material layers are well known in the OLED art. Such organic material layers typically have a refractive index of between 1.6 and 1.9, while indium tin oxide has a refractive index of approximately 1.8-2.0. Hence, the various layers 12 and 14 in an OLED have a refractive index range of 1.6 to 2.1.

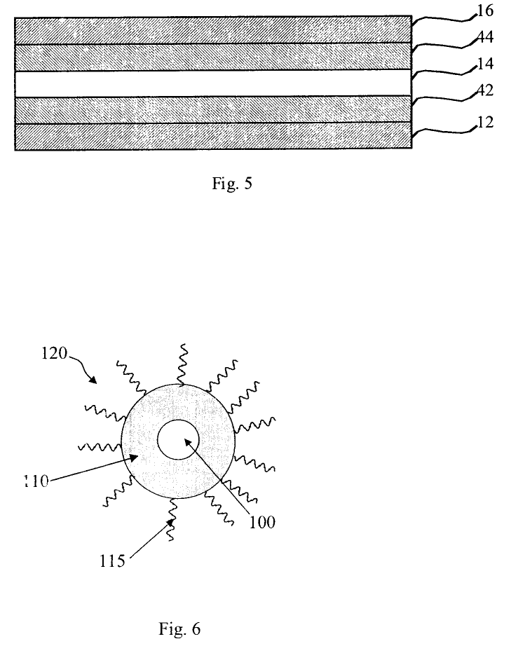

Alternatively, as shown in FIG. 5, the light-emitting layers 14 may comprise inorganic materials, for example, a light-emitting layer comprising inorganic, quantum dots that is initially colloidal during deposition. Such a light-emitting layer may be formed initially as a colloid of light-emitting particles such as quantum dots, dispersed in a solvent, coated over a substrate, and dried. Additional non-light-emitting, electrically conductive or semi-conductive particles may be included in the dispersion and, once dried, the dispersion may be annealed to form a polycrystalline, semi-conductor matrix. The polycrystalline semiconductor matrix then comprises the light-emitting layer 14. In various further embodiments of the present invention, the light-emissive device may further comprise one or more optional charge-injection, charge-transport, and/or charge-blocking layers 42, 44 formed between the light-emitting layer 14 and either of the electrodes 12, 16. In a further embodiment of the present invention, the electrodes 12, 16 and any optional charge-injection, charge-transport, and/or charge-blocking layers 42, 44 formed between the light-emitting layer 14 and either of the electrodes 12, 16, have a refractive index greater than the refractive index of the substrate 10. According to further embodiments of the present invention, any optional charge-injection, charge-transport, and/or charge-blocking layers 42, 44 may have a refractive index substantially greater than or equal to the refractive index of the light-emitting layer 14 and/or substantially equal to or less than the refractive index of the transparent electrode 16.

According to one embodiment of the present invention, a light-emitting diode (LED) device comprises a transparent substrate, one-or-more transparent thin-film transistors located over the substrate, one or more light-emitting elements formed over the transparent thin-film transistors, wherein each light-emitting element comprises, a first transparent extensive electrode formed at least partially over at least a portion of the one-or-more transparent thin-film transistors, at least one light-emitting layer comprising randomly-located quantum dots formed over the first transparent extensive electrode, and a second reflective electrode formed over the at least one layer of light-emitting material. The light-emitting layer may be a polycrystalline, semi-conductor matrix. The use of such a light-emitting layer according to an embodiment of the present invention provides advantages in performance. Because other prior-art quantum dot device are formed using, for example, epitaxial methods, the quantum dots may be aligned within a structure, for example, placing quantum dots in particular locations in a plurality of layers, similar to a crystal structure. Such an arrangement and process may damage underlying layers, for example, the thin-film transistors, and may not be suitable for forming a light-emitting device with structures similar to those of the present invention. Moreover, the regular arrangement of quantum dots may lead to diffraction effects or light filtering effects in emitted light or reflected ambient light. Hence, a light-emitting layer having randomly located nano-particles (e.g. quantum dots) may provide an advantage.

In various embodiments of the present invention, electrically conductive transparent layers and/or electrodes may be formed from metal oxides or metal alloys having an optical index of 1.8 or more. For example, organic devices typically employ sputtered indium tin oxide whose optical index may be in the range of 1.8 to 2.0. As taught in the prior art, such a metal oxide with such an optical index will cause a greater amount of light trapping, thereby reducing the light efficiency of such prior-art devices. According to various embodiments of the present invention, a transparent electrode, for example tin oxide, has an optical index greater or equal to optical index of the light-emissive layer. Hence, a transparent electrode with a greater optical index is preferred and may be formed by additional annealing steps, deposition at higher temperatures, or by employing materials having a greater optical index, as is known in the art. In an inorganic embodiment of the present invention, p-type and/or an n-type charge-injection, -transport, or -blocking layers 42 and 44, respectively, optionally employed to provide charge control, are typically formed from metal alloys and have optical indices of approximately greater than 1.8.

Substrates on which light-emitting devices are formed typically comprise glass or plastic, having an optical index of approximately 1.5. Hence, it will generally be the case that the electrodes 12, 16 and any charge-injection, -transport, and/or -blocking layers 42, 44 formed between the light-emitting layer 14 and either of the electrodes 12, 16, will have a refractive index greater than the refractive index of the substrate 10. Useful material for electrodes includes ITO, CdSe, ZnTe, SnO2, and AlZnO. These materials have typical refractive indices in the range of 1.8 to 2.7. Useful inorganic materials for charge-control layers include CdZnSe and ZnSeTe. In another embodiment of the present invention, the transparent electrode has an optical index greater than or equal to the optical index of the charge-control layers. Organic materials are also known in the art. Reflective electrodes may comprise evaporated or sputtered metals or metal alloys, including Al, Ag, and Mg and alloys thereof. Deposition processes for these materials are known in the art and include sputtering and evaporation. Some materials may also be deposited using ALD or CVD processes, as are known in the art. However, organic materials are more environmentally sensitive and may have limited lifetimes compared to inorganic materials.

Of course, the refractive indices of various materials may be dependent on the wavelength of light passing through them, so the refractive index values cited here for these materials are only approximate. In any case, the low-index layer 24 preferably has a refractive index at least 0.1 lower than that of the substrate, and thus will also typically have a refractive index lower than that of the organic layers. The low-index layer may comprise an optical isolation cavity and have a refractive index close to 1.

Transparent thin-film transistors that employ inorganic metal oxide semiconductors are known as discussed in the references cited above in the background of the Invention, and may comprise, e.g., zinc oxide, indium oxide, tin oxide, or cadmium oxide deposited with or without additional doping elements including transition metals such as aluminum. In a particular embodiment, the transparent thin-film transistors may be formed from zinc-oxide-based nano-particles as further discussed below. Such semiconductor materials may be transparent and are suitable for use with the present invention. Organic thin-film transistors, employing pentacene, for example, are also known.

According to an embodiment of the present invention, a method of making a light-emitting diode (LED) device, comprises the steps of: providing a transparent substrate; forming one-or-more transparent thin-film transistors located over the substrate; forming one or more light-emitting elements formed over the transparent thin-film transistors, wherein each light-emitting element comprises a first transparent extensive electrode formed at least partially over at least a portion of the one-or-more transparent thin-film transistors, at least one layer of light-emitting material formed over the first transparent extensive electrode, and a second reflective electrode formed over the at least one layer of light-emitting material; forming a low-index layer between the first transparent extensive electrode and the one-or-more thin-film transistors, the low-index layer having an optical index lower than that of the layer of light-emitting material; and forming a light-scattering layer between the low-index layer and the second reflective electrode, or formed as part of the second reflective electrode.

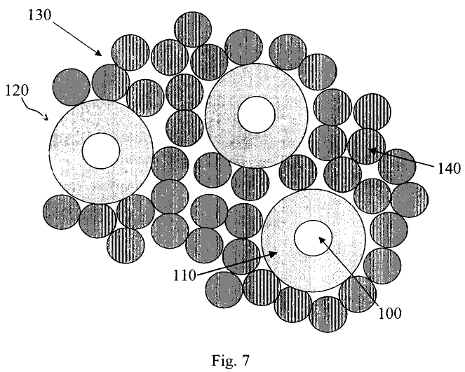

In further embodiments of the present invention and as illustrated in FIGS. 6 and 7, light-emitting layer 14 may comprise a polycrystalline layer of light-emitting particles 120, e.g. quantum dots, together with conductive or semi-conductive, non-light-emissive particles 140 located in the layer. The particles 140 may improve transfer of energy into the light-emissive particles 18. Such conductive or semi-conductive particles, for example, nano-particles, are known in the art. Agglomerations 130 of light-emissive particles 120 and, optionally, conductive or semi-conductive, non-emissive particles 140 may by considered to be within the present invention, as single particles located within the light-emissive layer 14.

Referring to FIGS. 6 and 7, for one embodiment of the present invention, the light-emissive particles 120 are quantum dots. Using quantum dots as the emitters in light-emitting diodes confers the advantage that the emission wavelength can be simply tuned by varying the size of the quantum dot particle. As such, spectrally narrow (resulting in a larger color gamut), multi-color emission can occur. If the quantum dots are prepared by colloidal methods [and not grown by high vacuum deposition techniques (S. Nakamura et al., Electronics Letter 34, 2435 (1998))], then the substrate no longer needs to be expensive or lattice matched to the LED semiconductor system. For example, the substrate could be glass, plastic, metal foil, or Si. Forming quantum dot LEDs using these techniques is highly desirably, especially if low cost deposition techniques are used to deposit the LED layers.

A schematic of a core/shell quantum dot 120 emitter is shown in FIG. 6. The particle contains a light-emitting core 100, a semiconductor shell 110, and organic ligands 115. Since the size of typical quantum dots is on the order of a few nanometers and commensurate with that of its intrinsic exciton, both the absorption and emission peaks of the particle are blue-shifted relative to bulk values (R. Rossetti et al., Journal of Chemical Physics 79, 1086 (1983)). As a result of the small size of the quantum dots, the surface electronic states of the dots have a large impact on the dot's fluorescence quantum yield. The electronic surface states of the light-emitting core 100 can be passivated either by attaching appropriate (e.g., primary amines) organic ligands 115 to its surface or by epitaxially growing another semiconductor (the semiconductor shell 110) around the light-emitting core 100. The advantages of growing the semiconductor shell 110 (relative to organically passivated cores) are that both the hole and electron core particle surface states can be simultaneously passivated, the resulting quantum yields are typically higher, and the quantum dots are more photostable and chemically robust. Because of the limited thickness of the semiconductor shell 110 (typically 1-2 monolayers), its electronic surface states also need to be passivated. Again, organic ligands 115 are the common choice. Taking the example of a CdSe/ZnS core/shell quantum dot 120, the valence and conduction band offsets at the core/shell interface are such that the resulting potentials act to confine both the holes and electrons to the core region. Since the electrons are typically lighter than the heavy holes, the holes are largely confined to the cores, while the electrons penetrate into the shell and sample its electronic surface states associated with the metal atoms (R. Xie et al., Journal of the American Chemical Society 127, 7480 (2005)). Accordingly, for the case of CdSe/ZnS core/shell quantum dots 120, only the shell's electron surface states need to be passivated; an example of a suitable organic ligand 115 would be one of the primary amines which forms a donor/acceptor bond to the surface Zn atoms (X. Peng et al., Journal of the American Chemical Society 119, 7019 (1997)). In summary, typical highly luminescent quantum dots have a core/shell structure (higher bandgap surrounding a lower band gap) and have non-conductive organic ligands 115 attached to the shell's surface.

Colloidal dispersions of highly luminescent core/shell quantum dots have been fabricated by many workers over the past decade (O. Masala and R. Seshadri, Annual Review Material Research 34, 41 (2004)). The light-emitting core 100 is composed of type IV (Si), III-V (InAs), or II-VI (CdTe) semiconductive material. For emission in the visible part of the spectrum, CdSe is a preferred core material since by varying the diameter (1.9 to 6.7 nm) of the CdSe core; the emission wavelength can be tuned from 465 to 640 nm. As is well-known in the art, visible emitting quantum dots can be fabricated from other material systems, such as, doped ZnS (A. A. Bol et al., Phys. Stat. Sol. B224, 291 (2001)). The light-emitting cores 100 are made by chemical methods well known in the art. Typical synthetic routes are decomposition of molecular precursors at high temperatures in coordinating solvents, solvothermal methods (disclosed by O. Masala and R. Seshadri, Annual Review Material Research 34, 41 (2004)), and arrested precipitation (disclosed by R. Rossetti et al., Journal of Chemical Physics 80, 4464 (1984)). The semiconductor shell 110 is typically composed of type II-VI semiconductive material, such as, CdS or ZnSe. The shell semiconductor is typically chosen to be nearly lattice matched to the core material and have valence and conduction band levels such that the core holes and electrons are largely confined to the core region of the quantum dot. Preferred shell material for CdSe cores is ZnSeₓS₁₋ₓ, with x varying from 0.0 to ˜0.5. Formation of the semiconductor shell 110 surrounding the light emitting core 100 is typically accomplished via the decomposition of molecular precursors at high temperatures in coordinating solvents (M. A. Hines et al., Journal of Physical Chemistry 100, 468 (1996)) or reverse micelle techniques (A. R. Kortan et al., Journal of American Chemical Society 112, 1327 (1990)).

As is well known in the art, two low-cost means for forming quantum dot films is depositing the colloidal dispersion of core/shell quantum dots 120 by drop casting and spin casting. Alternatively, spray or inkjet deposition may be employed. Common solvents for drop casting quantum dots are a 9:1 mixture of hexane: octane (C. B. Murray et al., Annual Review of Material Science 30, 545 (2000)). The organic ligands 115 need to be chosen such that the quantum dot particles are soluble in hexane. As such, organic ligands with hydrocarbon-based tails are good choices, such as, the alkylamines. Using well-known procedures in the art, the ligands coming from the growth procedure (TOPO, for example) can be exchanged for the organic ligand 115 of choice (C. B. Murray et al., Annual Review of Material Science 30, 545 (2000)). When depositing a colloidal dispersion of quantum dots, the requirements of the solvent are that it easily spreads on the deposition surface and the solvents evaporate at a moderate rate during the deposition process. It was found that alcohol-based solvents are a good choice; for example, combining a low boiling point alcohol, such as, ethanol, with higher boiling point alcohols, such as, a butanol-hexanol mixture, results in good film formation. Correspondingly, ligand exchange can be used to attach an organic ligand (to the quantum dots) whose tail is soluble in polar solvents; pyridine is an example of a suitable ligand. The quantum dot films resulting from these two deposition processes are luminescent, but non-conductive. The films are resistive since non-conductive organic ligands separate the core/shell quantum dot 120 particles. The films are also resistive since as mobile charges propagate along the quantum dots, the mobile charges get trapped in the core regions due to the confining potential barrier of the semiconductor shell 110.

Proper operation of inorganic LEDs typically requires low resistivity n-type and p-type transport layers, surrounding a conductive (nominally doped) and luminescent emitter layer. As discussed above, typical quantum dot films are luminescent, but insulating. FIG. 7 schematically illustrates a way of providing an inorganic light-emitting layer 14 that is simultaneously luminescent and conductive. The concept is based on co-depositing small (<2 nm), conductive or semi-conductive inorganic nanoparticles 140 along with the core/shell quantum dots 120 to form the inorganic light-emitting layer 14. A subsequent inert gas (Ar or N₂) anneal step is used to sinter the smaller inorganic nanoparticles 140 amongst themselves and onto the surface of the larger core/shell quantum dots 120. Sintering the inorganic nanoparticles 140, results in the creation of a conductive, polycrystalline, semiconductor agglomeration 130 useful in layer 14 or forming a matrix in layer 14. Through the sintering process, this agglomeration 130 is also connected to the core/shell quantum dots 120. As such, a conductive path is created from the edges of the inorganic light-emitting layer 14, through the polycrystalline, semiconductor agglomeration 130 and to each core/shell quantum dot 120, where electrons and holes recombine in the light emitting cores 100. It should also be noted that encasing the core/shell quantum dots 120 in the conductive, polycrystalline, semiconductor agglomeration 130 and by other layers has the added benefit that it protects the quantum dots environmentally from the effects of both oxygen and moisture.

The inorganic nanoparticles 140 need to be composed of semiconductive material, such as, type IV (Si), III-V (GaP), or II-VI (ZnS or ZnSe) semiconductors. In order to easily inject charge into the core/shell quantum dots 120, it is preferred that the inorganic nanoparticles 140 be composed of a semiconductor material with a band gap comparable to that of the semiconductor shell 110 material, more specifically a band gap within 0.2 eV of the shell material's band gap. For the case that ZnS is the outer shell of the core/shell quantum dots 120, then the inorganic nanoparticles 140 are composed of ZnS or ZnSSe with a low Se content. The inorganic nanoparticles 140 are made by chemical methods well known in the art. Typical synthetic routes are decomposition of molecular precursors at high temperatures in coordinating solvents, solvothermal methods (O. Masala and R. Seshadri, Annual Review of Material Research 34, 41 (2004)), and arrested precipitation (R. Rossetti et al., Journal of Chemical Physics 80, 4464 (1984)). As is well known in the art, nanometer-sized nanoparticles melt at a much-reduced temperature relative to their bulk counterparts (A. N. Goldstein et al., Science 256, 1425 (1992)). Correspondingly, it is desirable that the inorganic nanoparticles 140 have diameters less than 2 nm in order to enhance the sintering process, with a preferred size of 1-1.5 nm. With respect to the larger core/shell quantum dots 120 with ZnS shells, it has been reported that 2.8 nm ZnS particles are relatively stable for anneal temperatures up to 350° C. (S. B. Qadri et al., Physics Review B60, 9191 (1999)). Combining these two results, the anneal process has a preferred temperature between 250 and 300° C. and a duration up to 60 minutes, which sinters the smaller inorganic nanoparticles 140 amongst themselves and onto the surface of the larger core/shell quantum dots 120, whereas the larger core/shell quantum dots 120 remain relatively stable in shape and size.

To form an inorganic light-emitting layer 14, a co-dispersion of inorganic nanoparticles 140 and core/shell quantum dots 120 may be formed. Since it is desirable that the core/shell quantum dots 120 be surrounded by the inorganic nanoparticles 140 in the inorganic light-emitting layer 14, the ratio of inorganic nanoparticles 140 to core/shell quantum dots 120 is chosen to be greater than 1:1. A preferred ratio is 2:1 or 3:1. Depending on the deposition process, such as, spin casting or drop casting, an appropriate choice of organic ligands 115 is made. Typically, the same organic ligands 115 are used for both types of particles. In order to enhance the conductivity (and electron-hole injection process) of the inorganic light emitting layer 14, it is preferred that the organic ligands 115 attached to both the core/shell quantum dots 120 and the inorganic nanoparticles 140 evaporate as a result of annealing the inorganic light emitting layer 14 in an inert atmosphere. By choosing the organic ligands 115 to have a low boiling point, they can be made to evaporate from the film during the annealing process (C. B. Murray et al., Annual Review of Material Science 30, 545 (2000)). Consequently, for films formed by drop casting, shorter chained primary amines, such as, hexylamine are preferred; for films formed by spin casting, pyridine is a preferred ligand. Annealing thin films at elevated temperatures can result in cracking of the films due to thermal expansion mismatches between the film and the substrate. To avoid this problem, it is preferred that the anneal temperature be ramped from 25° C. to the anneal temperature (e.g., 160° C.) and subsequently from the anneal temperature back down to room temperature. A preferred ramp time is on the order of 30 minutes. The thickness of the resulting inorganic light-emitting layer 14 should be between 10 and 100 nm.

Following the anneal step, the core/shell quantum dots 120 would be devoid of an outer shell of organic ligands 115. For the case of CdSe/ZnS quantum dots, having no outer ligand shell would result in a loss of free electrons due to trapping by the shell's unpassivated surface states (R. Xie, Journal of American Chemical Society 127, 7480 (2005)). Consequently, the annealed core/shell quantum dots 120 would show a reduced quantum yield compared to the unannealed dots. To avoid this situation, the ZnS shell thickness needs to be increased to such an extent whereby the core/shell quantum dot electron wavefunction no longer samples the shell's surface states. Using calculational techniques well known in the art (S. A. Ivanov et al., Journal of Physical Chemistry 108, 10625 (2004)), the thickness of the ZnS shell needs to be at least 5 monolayers (ML) thick in order to negate the influence of the electron surface states. However, up to a 2 ML thick shell of ZnS can be directly grown on CdSe without the generation of defects due to the lattice mismatch between the two semiconductor lattices (D. V. Talapin et al., Journal of Physical Chemistry 108, 18826 (2004)). To avoid the lattice defects, an intermediate shell of ZnSe can be grown between the CdSe core and the ZnS outer shell. This approach was taken by Talapin et al. (D. V. Talapin et al., Journal of Physical Chemistry B108, 18826 (2004)), where they were able to grow up to an 8 ML thick shell of ZnS on a CdSe core, with an optimum ZnSe shell thickness of 1.5 ML. More sophisticated approaches can also be taken to minimize the lattice mismatch difference, for instance, smoothly varying the semiconductor content of the intermediate shell from CdSe to ZnS over the distance of a number of monolayers (R. Xie et al., Journal of the American Chemical Society 127, 7480 (2005)). In sum, the thickness of the outer shell is made sufficiently thick so that no free carrier samples the electronic surface states. Additionally, if necessary, intermediate shells of appropriate semiconductor content are added to the quantum dot in order to avoid the generation of defects associated with thick semiconductor shells 110.

As a result of surface plasmon effects (K. B. Kahen, Applied Physics Letters 78, 1649 (2001)), having metal layers adjacent to emitter layers results in a loss in emitter efficiency. Consequently, it is advantageous to space the emitters' layers from any metal contacts by sufficiently thick (at least 150 nm) charge transport layers (e.g. 42, 44) or conductive layers. Finally, not only do transport layers inject electron and holes into the emitter layer, but also, by proper choice of materials, they can prevent the leakage of the carriers back out of the emitter layer. For example, if the inorganic nanoparticles 140 were composed of ZnS_{0.5}Se_{0.5} and the transport layers were composed of ZnS, then the electrons and holes would be confined to the emitter layer by the ZnS potential barrier. Suitable materials for the p-type transport layer include II-VI and III-V semiconductors. Typical II-VI semiconductors are ZnSe, ZnS, or ZnTe. Only ZnTe is naturally p-type, while ZnSe and ZnS are n-type. To get sufficiently high p-type conductivity, additional p-type dopants should be added to all three materials. For the case of II-VI p-type transport layers, possible candidate dopants are lithium and nitrogen. For example, it has been shown in the literature that Li₃N can be diffused into ZnSe at ˜350° C. to create p-type ZnSe, with resistivities as low as 0.4 ohm-cm (S. W. Lim, Applied Physics Letters 65, 2437 (1994)).

Suitable materials for n-type transport layers include II-VI and III-V semiconductors. Typical II-VI semiconductors are ZnSe or ZnS. As for p-type transport layers, to get sufficiently high n-type conductivity, additional n-type dopants should be added to the semiconductors. For the case of II-VI n-type transport layers, possible candidate dopants are the Type III dopants of Al, In, or Ga. As is well known in the art, these dopants can be added to the layer either by ion implantation (followed by an anneal) or by a diffusion process (P. J. George et al., Applied Physics Letters 66, 3624 [1995]). A more preferred route is to add the dopant in-situ during the chemical synthesis of the nanoparticle. Taking the example of ZnSe particles formed in a hexadecylamine (HDA)/TOPO coordinating solvent (M. A. Hines et al., Journal of Physical Chemistry B102, 3655 [1998]), the Zn source is diethylzinc in hexane and the Se source is Se powder dissolved in TOP (forming TOPSe). If the ZnSe were to be doped with Al, then a corresponding percentage (a few percent relative to the diethylzinc concentration) of trimethylaluminum in hexane would be added to a syringe containing TOP, TOPSe, and diethylzinc. In-situ doping processes, like these, have been successfully demonstrated when growing thin films by a chemical bath deposition process (J. Lee et al., Thin Solid Films 431-432, 344 [2003]). In particular embodiments of the present invention, methods for forming the transparent thin-film transistors may be employed that are compatible with the use of flexible substrates, in particular the use of low-heat processes.

### First Method

In a first embodiment of the present invention employing a low-temperature process for forming the transparent thin-film transistors, zinc-oxide-based nano-particles are employed as described in copending, commonly assigned U.S. Ser. No. 11/155,436, filed Jun. 16, 2005, the disclosure of which is incorporated herein by reference. In a preferred embodiment, the zinc-oxide-based semiconductor materials are “n-type,” although, through the use of suitable dopants, p-type materials are also envisioned. The zinc-oxide-based semiconductor material can contain other metals capable of forming semiconducting oxides such as indium, tin, or cadmium, and combinations thereof. Minor amounts of acceptor dopants can also be included.

The method of making a thin film comprising a zinc-oxide-based semiconductor comprises:

(a) applying, to a substrate, a seed coating comprising a colloidal solution of zinc-oxide-based nanoparticles having an average primary particle size of 5 to 200 nm;

(b) drying the seed coating to form a porous layer of zinc-oxide-based nanoparticles;

optionally annealing the porous layer of zinc-oxide-based nanoparticles at a temperature higher than the temperature of step (a) or (b);

(c) applying, over the porous layer of nanoparticles, an overcoat solution comprising a soluble zinc-oxide-precursor compound that converts to zinc oxide upon annealing, to form an intermediate composite film;

(d) drying the intermediate composite film; and

(e) annealing the dried intermediate composite film at a temperature of at least 50° C. to produce a semiconductor film comprising zinc-oxide-based nanoparticles supplemented by additional zinc oxide material formed by the conversion of the zinc-oxide-precursor compound during the annealing of the composite film.

In one embodiment of the present invention, the LED device is constructed using a process for fabricating a thin film transistor, preferably by solution-phase deposition of the n-channel semiconductor film onto a substrate, preferably wherein the substrate temperature is at a temperature of no more than 300° C. during the deposition. In one embodiment, the nanoparticles are applied at room temperature followed by an annealing step carried out, typically, for one hour or less at a substrate temperature of 300° C. or less. Laser annealing may also be employed to allow the semiconductor to reach higher temperatures while maintaining relatively low substrate temperatures.

The invention is also directed to an LED display employing a transistor comprising a zinc-oxide-based semiconductor, preferably on a flexible substrate, made by the present process.

Semiconductor films made by the present method are capable of exhibiting, in the film form, excellent field-effect electron mobility of greater than 0.01 cm²/Vs and on-off ratios of greater than 10⁴, in which performance properties are sufficient for use in a variety of relevant technologies, including active matrix display backplanes.

A TFT structure includes, in addition to the zinc-oxide-based semiconductor, conducting electrodes, commonly referred to as a source and a drain, for injecting a current into the zinc-oxide-based semiconductor. One embodiment of the present invention is directed to the use of such n-channel semiconductor films in thin film transistors each comprising spaced apart first and second contact means connected to an n-channel semiconductor film. A third contact means can be spaced from said semiconductor film by an insulator, and adapted for controlling, by means of a voltage applied to the third contact means, a current between the first and second contact means through said film. The first, second, and third contact means can correspond to a drain, source, and gate electrode in a field effect transistor.

Preferably, the seed coating is applied to the substrate at a level of 0.02 to 1 g/m² of nanoparticles, by dry-weight. The overcoat solution is preferably applied at a level of 2×10⁻⁴ to 0.01 moles/m² of precursor compound. In a preferred embodiment, the molar ratio of nanoparticles to theoretically converted zinc-oxide precursor compound is approximately 0.02 to 60, based on moles of ZnO and precursor compound present.

The seed coating and the overcoat can be applied by various methods, including conventional coating techniques for liquids. In one embodiment, the seed coating and/or the overcoat solution is applied using an inkjet printer. The inkjet printer can be a continuous or drop-on-demand inkjet printer. In a conventional inkjet printer, the method of inkjet printing a semiconductor film on a substrate element typically comprises: (a) providing an inkjet printer that is responsive to digital data signals; (b) loading a first printhead with the seed solution; (c) printing on the substrate using the seed solution in response to the digital data signals; (d) loading a second printhead with the overcoat solution (e) printing over the first coating using the overcoat solution in response to the digital data signals; and (f) annealing the printed substrate.

Other coating techniques include spin coating, extrusion coating, hopper coating, dip coating, or spray coating. In a commercial scale process, the semiconductor film can be coated on a web substrate which is later divided into individual semiconductor films. Alternately, an array of semiconductor films can be coated on a moving web.

For example, a layer of zinc-oxide-based nanoparticles may be applied by spin coating and subsequently annealed for about 10 seconds to 10 minute, preferably 1 minute to about 5 minutes in certain instances, at a temperature of about 50 to 500° C., preferably about 130 C to about 300° C., suitably in an ambient environment.

A semiconductor material, for use in an atmospheric process, must display several characteristics. In typical applications of a thin film transistor, the desire is for a switch that can control the flow of current through the device. As such, it is desired that when the switch is turned on a high current can flow through the device. The extent of current flow is related to the semiconductor charge carrier mobility. When the device is turned off, it is desired that the current flow be very small. This is related to the charge carrier concentration. Furthermore, it is desired that the device be weakly or not at all influenced by visible light. In order for this to be true, the semiconductor band gap must be sufficiently large (>3 eV) so that exposure to visible light does not cause an inter-band transition. A material that capable of yielding a high mobility, low carrier concentration, and high band gap is ZnO. Furthermore, in a real high-volume web-based atmospheric manufacturing scheme, it is highly desirable that the chemistries used in the process are both cheap and of low toxicity, which can be satisfied by the use of ZnO and the majority of its precursors.

As indicated above, the present method of making the zinc-oxide-based semiconductor thin film, for use in thin film transistors, employs nanoparticles of a zinc-oxide-based material. The zinc-oxide-based semiconductor material can contain minor amounts of other metals capable of forming semiconducting oxides such as indium, tin, or cadmium, and combinations thereof. For example, Chiang, H. Q. et al., “High mobility transparent thin-film transistors with amorphous zinc tin oxide channel layer,” Applied Physics Letters 86, 013503 (2005) discloses zinc tin oxide materials. Also, minor amounts of optional acceptor or donor dopants, preferably less than 10 weight percent, can also be included in the nanoparticles before or after deposition.

Accordingly, the term “zinc-oxide-based” refers to a composition comprising mostly zinc oxide, preferably at least 80 percent, but allowing additives or mixtures with minor amounts of other metal oxides, which semiconductor compositions are known to the skilled artisan.

Although undoped zinc-oxide-based nanoparticles can be employed in the present invention, the resistivity of the ZnO may be enhanced by substitutional doping with an acceptor dopant such as, for example, N, B, Cu, Li, Na, K, Rb, P, As, and mixtures thereof. Alternatively, p-type zinc-oxide films can be achieved, by the use of various p-type dopants and doping techniques. For example, U.S. Pat. No. 6,610,141 by White et al. discloses zinc-oxide films containing a p-type dopant, for use in LEDs (light emitting devices), LDs (laser diodes), photodetectors, solar cells or other electrical devices where both n-type and p-type materials may be required for one or more multiple p-n junctions. White et al. employ diffusion of arsenic from a GaAs substrate to produce an arsenic-doped zinc-oxide-based film. U.S. Pat. No. 6,727,522 also describes various dopants for p-type zinc-oxide-based semiconductor films, in addition to n-type dopants. Electrical devices in which zinc oxide is used as the n-type semiconductor and a different metal oxide, such as copper oxide or sodium cobalt oxide, is used as a p-type metal oxide are also known, as for example, described in EP 1324398. Thus, the present invention can be used to make one or more semiconductor thin films in the same electrical device having a p-n junction, either by variously doped zinc-oxide-based semiconductor thin films made by the present method or by a zinc-oxide-based semiconductor thin film in combination with one or more other metal-oxide semiconductor thin films known in the art. For example, an electrical device made according to the present invention can include a p-n junction formed using a zinc-oxide-based thin film semiconductor made by the present method in combination with a thin film semiconductor of complementary carrier type as known in the art.

The thickness of the channel layer may vary, and according to particular examples it can range from about 5 nm to about 100 nm. The length and width of the channel is determined by the pixel size and the design rules of the system under construction. Typically, the channel width may vary from 10 to 1000 nm. The channel length may vary, and according to particular examples it can range from about 1 to about 100 μm.

The entire process of making the thin film transistor or electronic device, or at least the production of the thin film semiconductor, can be carried out below a support temperature of about 500° C., more preferably below 250° C., most preferably below about 150° C., and even more preferably below about 100° C., or even at temperatures around room temperature (about 25° C. to 70° C.). The temperature selection generally depends on the support and processing parameters known in the art, once one is armed with the knowledge of the present invention contained herein. These temperatures are well below traditional integrated circuit and semiconductor processing temperatures, which enables the use of any of a variety of relatively inexpensive supports, such as flexible polymeric supports. Thus, the invention enables production of relatively inexpensive circuits containing thin film transistors with significantly improved performance.

One embodiment of the present invention employs a process for fabricating a thin film transistor, preferably by solution-phase deposition of the semiconductor thin film onto a substrate, preferably wherein the substrate temperature is at a temperature of no more than 300° C. during the deposition. In such an embodiment, the nanoparticles are applied at room temperature followed by an annealing step carried out, typically, for one hour or less at a substrate temperature of 300° C. or less. Laser annealing may also be employed to allow the semiconductor to reach higher temperatures while maintaining relatively low substrate temperatures.

The nanoparticles used in embodiments of the present invention can be formed as a colloidal sol for application to the substrate. Preferably, nanoparticles having an average primary particles size of 5 to 200 nm, more preferably from 20 to 150 or from 20 to 100 nm, are colloidally stabilized in the coating solution, by charge, in the absence of surfactant. Charge stabilized sols are stabilized by repulsion between particles based on like surface charges. See C. Jeffrey Brinker and George W. Scherer, The Physics and Chemistry of Sol-Gel Processing, Academic Press (New York 1989).

Zinc-oxide-based nanoparticles can be formed from the reaction of an organometallic precursor such as zinc acetate that is hydrolyzed with a base such as potassium hydroxide. Other organometallic precursor compounds can include, for example, zinc acetylacetonate, zinc formate, zinc hydroxide, zinc chloride, zinc nitrate, their hydrates, and the like. Preferably, the organometallics precursor compound is a zinc salt of a carboxylic acid or a hydrate thereof, more preferably zinc acetate or a hydrate thereof. Optional doping materials can include, for example, aluminum nitrate, aluminum acetate, aluminum chloride, aluminum sulfate, aluminum formate, gallium nitrate, gallium acetate, gallium chloride, gallium formate, indium nitrate, indium acetate, indium chloride, indium sulfate, indium formate, boron nitrate, boron acetate, boron chloride, boron sulfate, boron formate, and their hydrates.

Preferably, after particle formation, the level of ions is reduced by washing to obtain a stable dispersion. Too many ions in solution can cause a screening of the particles from each other so that the particles approach too closely leading to aggregation and thus poor dispersion. Repeated washings allow the inorganic ion level to reach a preferred concentration of below 1 mM. Preferably, the level of organic compounds, or salts thereof, is maintained below a level of 5 mM.

In one embodiment, a substrate is provided and a layer of the semiconductor material as described above can be applied to the substrate, electrical contacts being made to the layer. The exact process sequence is determined by the structure of the desired semiconductor component. Thus, in the production of a field effect transistor, for example, a gate electrode can be first deposited on a flexible substrate, for example a vacuum or solution deposited metal or organic conductor. The gate electrode can then be insulated with a dielectric and then source and drain electrodes and a layer of the n-channel semiconductor material can be applied on top. The structure of such a transistor and hence the sequence of its production can be varied in the customary manner known to a person skilled in the art. Thus, alternatively, a gate electrode can be deposited first, followed by a gate dielectric, then the semiconductor can be applied, and finally the contacts for the source electrode and drain electrode deposited on the semiconductor layer. A third structure could have the source and drain electrodes deposited first, then the semiconductor, with dielectric and gate electrode deposited on top.

The skilled artisan will recognize other structures can be constructed and/or intermediate surface modifying layers can be interposed between the above-described components of the thin film transistor. In most embodiments, a field effect transistor comprises an insulating layer, a gate electrode, a semiconductor layer comprising a ZnO material as described herein, a source electrode, and a drain electrode, wherein the insulating layer, the gate electrode, the semiconductor layer, the source electrode, and the drain electrode are in any sequence as long as the gate electrode and the semiconductor layer contact opposite sides of the insulating layer, and the source electrode and the drain electrode both contact the semiconductor layer.

A thin film transistor (TFT) is an active device, which is the building block for electronic circuits that switch and amplify electronic signals. Attractive TFT device characteristics include a low voltage to turn it on, a high transconductance or (device current)/(gate) control-voltage ratio, and a high ‘on’ (Vg>0) current to ‘off’ (Vg≦0) current ratio. In one embodiment, the substrate may be a polymer, such as PET, PEN, KAPTON or the like. Source and drain conducting electrodes can be patterned on the substrate. The zinc-oxide-based semiconductor is then coated, followed by a gate-insulating layer such as SiO₂ or Al₂O₃ or a solution coated polymer. Finally, a gate-conducting electrode is deposited on the gate-insulating layer. One of skill in the art will recognize that this is one of many possible TFT fabrication schemes.

In the operation of such a TFT device, a voltage applied between the source and drain electrodes establishes a substantial current flow only when the control gate electrode is energized. That is, the flow of current between the source and drain electrodes is modulated or controlled by the bias voltage applied to the gate electrode. The relationship between material and device parameters of the zinc-oxide-based semiconductor TFT can be expressed by the approximate equation (see Sze in Semiconductor Devices-Physics and Technology, John Wiley & Sons (1981)):

$${I}_{d} = \frac{W}{2 L} μ {C ( {V}_{g} - {V}_{th} )}^{2}$$

where I_{d} is the saturation source-drain current, C is the geometric gate capacitance, associated with the insulating layer, W and L are physical device dimensions, μ is the carrier (hole or electron) mobility in the zinc-oxide-based semiconductor, and V_{g} is the applied gate voltage, and Vₜₕ is the threshold voltage. Ideally, the TFT allows passage of current only when a gate voltage of appropriate polarity is applied. However, with zero gate voltage, the “off” current between source and drain will depend on the intrinsic conductivity σ of the zinc-oxide-based semiconductor,

σ=nqμ

where n is the charge carrier density and q is the charge, so that

(I_{sd})=σ(Wt/L)V_{sd}@Vg=0

wherein t is the zinc-oxide-based semiconductor layer thickness and V_{sd} is the voltage applied between source and drain. Therefore, for the TFT to operate as a good electronic switch, e.g. in a display, with a high on/off current ratio, the semiconductor needs to have high carrier mobility but very small intrinsic conductivity, or equivalently, a low charge carrier density. On/off ratios >10⁴ are desirable for practical devices.

### Second Method

In an alternative embodiment of the present invention, the transparent thin-film transistors may be formed by chemical or atomic layer deposition (ALD), either in a vacuum, reduced pressure enclosure or in an atmospheric pressure enclosure, as described in copending, commonly assigned U.S. Ser. No. 11/392,007, filed Mar. 29, 2006, the disclosure of which is incorporated herein by reference. This process is an advantageous variation of ALD that allows for continuous exposure of a substrate to the gaseous materials used in the ALD reaction system while at the same time avoiding the use of a vacuum purge of each of the reactive gaseous materials after exposure to the substrate. Without wishing to be bound by theory, the transverse flow is believed to supply and remove gaseous materials from the surface of the substrate substantially by a diffusion process through a thin diffusion layer. The diffusion gradient is maintained, through the diffusion layer, by continuous flow of new gaseous material over the diffusion layer. The transverse flow can be provided by the use of elongated outlet channels openly positioned over the surface of the substrate.

In one method useful for the present invention, a process for thin-film material deposition onto a substrate comprises: simultaneously directing a series of gas flows along elongated channels such that the gas flows are substantially parallel to a surface of the substrate and substantially parallel to each other, whereby the gas flows are substantially prevented from flowing in the direction of the adjacent elongated channels, and wherein the series of gas flows comprises, in order, at least a first reactive gaseous material, inert purge gas, and a second reactive gaseous material, optionally repeated a plurality of times, wherein the first reactive gaseous material is capable of reacting with a substrate surface treated with the second reactive gaseous material.

In another method useful for the present invention, a process for thin-film material deposition onto a substrate comprises:

(a) providing a plurality of gaseous materials comprising at least first, second, and third gaseous materials, wherein the first and second gaseous materials are reactive with each other such that when one of the first or second gaseous materials are on the surface of the substrate the other of the first or second gaseous materials will react to deposit at least an atomic layer of material on the substrate and wherein the third gasesous material is inert with respect to reacting with the first or second gaseous materials;

(b) providing a substrate to be subjected to thin-film deposition of a material; and

(c) flowing the first, second and third gaseous materials into, respectively, into a plurality of elongated channels, each channel extending in a length direction substantially in parallel, the channels comprising at least a first, second, and third output channel for, respectively, the first, second and third gaseous material, wherein each of the channels substantially directs flow of the corresponding one of the first, second, or third gaseous materials along the length direction of the channel, substantially parallel to the substrate surface, preferably at a distance of under 1 mm from the substrate surface.

During the process, the substrate or distribution manifold for the gaseous materials, or both, is capable of providing relative movement between the output face of the distribution manifold and the substrate while maintaining the pre-designed close proximity.

In a preferred embodiment, the process can be operated with continuous movement of a substrate being subjected to thin film deposition, wherein the process is capable of conveying the support on or as a web past the distribution manifold, preferably in an unsealed environment to ambient at substantially atmospheric pressure.

The method provides a compact process for atomic layer deposition onto a substrate that is well suited to a number of different types of substrates and deposition environments. It also allows operation, in preferred embodiments, under atmospheric pressure conditions and is adaptable for deposition on a web or other moving substrate, including deposition onto a large area substrate. It is still a further advantage of the method employed for the present invention, that it can be employed in low-temperature processes at atmospheric pressures, which process may be practiced in an unsealed environment, open to ambient atmosphere.

The process employed offers a significant departure from conventional approaches to ALD, employing a compact distribution system for delivery of gaseous materials to a substrate surface, adaptable to deposition on larger and web-based substrates and capable of achieving a highly uniform thin-film deposition at improved throughput speeds. The process employs a continuous (as opposed to pulsed) gaseous material distribution. The process also allows operation at atmospheric or near-atmospheric pressures as well as under vacuum and is capable of operating in an unsealed or open-air environment.

In one embodiment, two reactive gases are used, a first molecular precursor and a second molecular precursor. Gases are supplied from a gas source and can be delivered to the substrate, for example, via a distribution manifold. Metering and valving apparatus for providing gaseous materials to a distribution manifold can be used. A continuous supply of gaseous materials for the system is provided for depositing a thin film of material on a substrate. With respect to a given area of the substrate (referred to as the channel area), a first molecular precursor or reactive gaseous material is directed to flow in a first channel transversely over the channel area of the substrate and reacts therewith. Relative movement of the substrate and the multi-channel flows in the system occurs, after which second channel (purge) flow with inert gas occurs over the given channel area. Then relative movement of the substrate and the multi-channel flows enables the given channel area to be subjected to atomic layer deposition in which a second molecular precursor now transversely flows (substantially parallel to the surface of the substrate) over the given channel area of the substrate and reacts with the previous layer on the substrate to produce (theoretically) a monolayer of a desired material. Often in such processes, a first molecular precursor is a metal-containing compound in gas form, and the material deposited is a metal-containing compound, for example, an organometallic compound such as diethylzinc. In such an embodiment, the second molecular precursor can be, for example, a non-metallic oxidizing compound.

Relative movement of the substrate and the multi-channel flows then enables the next step in which again an inert gas is used, this time to sweep excess second molecular precursor from the given channel area from the previous step. Then, relative movement of the substrate and the multi-channels occurs again, which sets the stage for a repeat sequence. The cycle is repeated as many times as is necessary to establish a desired film. In the present embodiment of the process, the steps are repeated with respect to a given channel area of the substrate, corresponding to the area covered by a flow channel. Meanwhile the various channels are being supplied with the necessary gaseous materials. Simultaneous with this sequence, other adjacent channel areas may be processed simultaneously, which results in multiple channel flows in parallel.

The primary purpose of the second molecular precursor is to condition the substrate surface back toward reactivity with the first molecular precursor. The second molecular precursor also provides material from the molecular gas to combine with metal at the surface, forming compounds such as an oxide, nitride, sulfide, etc, with the freshly deposited metal-containing precursor.

The method employed to construct the transparent thin-film transistors of the present invention is unique in that the continuous ALD purge does not need to use a vacuum purge to remove a molecular precursor after applying it to the substrate. Purge steps are expected by most researchers to be the most significant throughput-limiting step in ALD or chemical vapor deposition (CVD) processes.

Assuming that, for the two reactant gases, when the first reaction gas flow is supplied and flowed over a given substrate area, atoms of the first reaction gas are chemically adsorbed on a substrate, resulting in a layer and a ligand surface. Then, the remaining first reaction gas is purged with an inert gas. Then, the flow of the second reaction gas occurs and a chemical reaction proceeds between the adsorbed atoms and the second reaction gas, resulting in a molecular layer on the substrate. The remaining second reaction gas and by-products of the reaction are purged. The thickness of the thin film can be increased by repeating the process cycle many times.

Because the film can be deposited one monolayer at a time it tends to be conformal and have uniform thickness.

This process can been used to deposit a variety of materials useful for forming transparent thin-film transistors, including II-VI and III-V compound semiconductors, metals, and metal oxides and nitrides. Depending on the process, films can be amorphous, epitaxial or polycrystalline. Thus, in various embodiments of the present method a broad variety of process chemistries may be practiced, providing a broad variety of final films. Binary compounds of metal oxides that can be formed, for example, are tantalum pentoxide, aluminum oxide, titanium oxide, niobium pentoxide, zirconium oxide, hafnium oxide, zinc oxide, lanthium oxide, yttrium oxide, cerium oxide, vanadium oxide, molybdenum oxide, manganese oxide, tin oxide, indium oxide, tungsten oxide, silicon dioxide, and the like.

Thus, oxides that can be made using the present process include, but are not limited to: Al₂O₃, TiO₂, Ta₂O₅, Nb₂O₅, ZrO₂, HfO₂, SnO₂, ZnO, La₂O₃, Y₂O₃, CeO₂, Sc₂O₃, Er₂O₃, V₂O₅, SiO₂, and In₂O₃. Nitrides that can be made using the process of the present invention include, but are not limited to: AlN, TaNₓ, NbN, TiN, MoN, ZrN, HfN, and GaN. Fluorides that can be made using the process of the present invention include, but are not limited to: CaF₂, SrF₂, and ZnF₂. Metals that can be made using the process of the present invention include, but are not limited to: Pt, Ru, Ir, Pd, Cu, Fe, Co, and Ni. Carbides that can be made using the process of the present invention include, but are not limited to: TiC, NbC, and TaC. Mixed structure oxides that can be made using the process of the present invention include, but are not limited to: AlTiNₓ, AlTiOₓ, AlHfOₓ, AlSiOₓ, and HfSiOₓ. Sulfides that can be made using the process of the present invention include, but are not limited to: ZnS, SrS, CaS, and PbS. Nanolaminates that can be made using the process of the present invention include, but are not limited to: HfO₂/Ta₂O₅, TiO₂/Ta₂O₅, TiO₂/Al₂O₃, ZnS/Al₂O₃, ATO (AlTiO), and the like. Doped materials that can be made using the process of the present invention include, but are not limited to: ZnO:Al, ZnS:Mn, SrS:Ce, Al₂O₃:Er, ZrO₂:Y and the like.

It will be apparent to the skilled artisan that alloys of two, three or more metals may be deposited, compounds may be deposited with two, three or more constituents, and such things as graded films and nano-laminates may be produced as well. These variations are simply variants using particular embodiments of the method described in alternating cycles.

Various gaseous materials that may be reacted are also described in Handbook of Thin Film Process Technology, Vol. 1, edited by Glocker and Shah, Institute of Physics (IOP) Publishing, Philadelphia 1995, pages B1.5:1 to B1.5:16, hereby incorporated by reference; and Handbook of Thin Film Materials, edited by Nalwa, Vol. 1, pages 103 to 159, hereby incorporated by reference. In Table V1.5.1 of the former reference, reactants for various ALD processes are listed, including first metal-containing precursors of Group II, III, IV, V, VI and others. In the latter reference, Table IV lists precursor combinations used in various ALD thin film processes.

Although oxide substrates provide groups for ALD deposition, plastic substrates can be used by suitable surface treatment.

While the discussion above describes the use of novel methods for forming transparent thin-film transistors for the LED device of the present invention, these methods may also be employed for forming other active-matrix electronic components such as capacitors, resistive elements, and conductors. The use of transparent elements of these types provides increased transparency of the active-matrix area and improves light output from the device. However, some non-transparent components may be employed with the present invention. If the non-transparent components are reflective, emitted light that impinges on them may be reflected and re-scattered until the light is emitted. If they are absorptive, the light is lost, hence it is preferred that the relative amount of active-matrix components that are absorptive be minimized or that the light-emission area 60 be patterned so that light is not emitted above such light-absorptive areas. Such patterning may be done using careful layout and the processes described above. In a preferred embodiment of the present invention, photo-reactive materials are not employed in the light emissive areas.

The present invention may be employed in display devices. In a preferred embodiment, the present invention is employed in a flat-panel OLED device composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Alternatively, inorganic, light-emitting particles, for example quantum dots as disclosed in co-pending, commonly assigned U.S. patent application Ser. No. 11/668,039, filed 29 Jan. 2007, may be employed. Many combinations and variations of light-emitting displays can be used to fabricate such a device, including both active- and passive-matrix LED.

The invention has been described in detail with particular reference to certain preferred embodiments thereof, but it will be understood that variations and modifications can be effected within the spirit and scope of the invention.

### PARTS LIST

10 transparent substrate
12 transparent electrode
14 light-emitting layer(s)
16 reflective electrode
17 transparent conductive layer
18 reflective layer
19 multi-layer reflective electrode
20 cover
22 scattering layer
23 second layer
24 low-index layer
30 thin-film transistors
32 insulating planarization layer
34 insulating layer
42 charge-control layer
44 charge-control layer
60 emissive area
62 light-emitting element
64 light ray
100 light emitting core
110 shell
115 organic ligands
120 light-emissive particles
130 semiconductor agglomeration
140 conductive or semi-conductive inorganic nanoparticles

1. A light-emitting diode (LED) device, comprising:
a transparent substrate;
one-or-more transparent thin-film transistors located over the substrate;
one or more light-emitting elements formed over the transparent thin-film transistors, wherein each light-emitting element comprises:
a first transparent extensive electrode formed at least partially over at least a portion of the one-or-more transparent thin-film transistors;
at least one layer of light-emitting material formed over the first transparent extensive electrode; and
a second reflective electrode formed over the at least one layer of light-emitting material;
a low-index layer formed between the first transparent extensive electrode and the one-or-more thin-film transistors, the low-index layer having an optical index lower than that of the layer of light-emitting material, the transparent thin-film transistors, and the transparent substrate; and
a light-scattering layer formed between the low-index layer and the second reflective electrode, or formed as part of the second reflective electrode.

2. The LED device of claim 1, wherein the scattering layer is formed between the low-index layer and the first transparent extensive electrode.

3. The LED device of claim 1, wherein the second reflective electrode is a multi-layer electrode including a transparent layer and a reflective layer, the transparent layer being between the reflective layer and the one-or-more layer of light-emitting material.

4. The LED device of claim 3, wherein the scattering layer is formed between at least a portion of the transparent layer and a portion of the reflective layer.

5. The LED device of claim 1, wherein the thin-film transistors are inorganic.

6. The LED device of claim 1, wherein the thin-film transistors comprise metal oxide.

7. The LED device of claim 6, wherein the metal oxide comprises zinc oxide, doped zinc oxide, or aluminum zinc oxide.

8. The LED device of claim 1, wherein the light-emitting layer comprises a layer of inorganic light-emitting particles.

9. The LED device of claim 8, wherein the inorganic light-emitting particles are quantum dots.

10. The LED device of claim 1, wherein the light-emitting layer further comprises non-light-emitting, conductive or semi-conductive particles.

11. The LED device of claim 1, wherein the light-emitting layer comprises a polycrystalline layer of inorganic light-emitting particles and non-light-emitting, conductive or semi-conductive particles sintered to the inorganic light-emitting particles.

12. The LED device of claim 1 further comprising one or more charge-injection, charge-transport, and/or charge-blocking layers formed between the light-emitting layer and either of the electrodes.

13. The LED device of claim 12, wherein the charge-injection, charge-transport, and/or charge-blocking layers have a refractive index substantially equal to or greater than a refractive index of the light-emitting layer and substantially equal to or less than a refractive index of the transparent electrode.

14. The LED device of claim 1, wherein the substrate comprises a polymer or a glass.

15. The LED device of claim 1, wherein the transparent thin-film transistors are formed from zinc-oxide-based nano-particles.

16. The LED device of claim 1, wherein the transparent thin-film transistors are formed by employing a vapor deposition process that alternately provides a first reactive gaseous material and a second reactive gaseous material, wherein the first reactive gaseous material is capable of reacting with the layers treated with the second reactive gaseous material.

17. The LED device of claim 1, wherein the transparent thin film transistors are formed using either an atomic layer deposition process, or a vacuum chemical vapor deposition process, or an atmospheric chemical vapor deposition process.

18. A light-emitting diode (LED) device, comprising:
a transparent substrate;
one-or-more transparent thin-film transistors located over the substrate;
one or more light-emitting elements formed over the transparent thin-film transistors, wherein each light-emitting element comprises:
a first transparent extensive electrode formed at least partially over at least a portion of the one-or-more transparent thin-film transistors;
at least one light-emitting layer comprising randomly-located quantum dots formed over the first transparent extensive electrode; and
a second reflective electrode formed over the at least one layer of light-emitting material.

19. A method of making a light-emitting diode (LED) device, comprising:
providing a transparent substrate;
forming one-or-more transparent thin-film transistors located over the substrate;
forming one or more light-emitting elements formed over the transparent thin-film transistors, wherein each light-emitting element comprises:
a first transparent extensive electrode formed at least partially over at least a portion of the one-or-more transparent thin-film transistors;
at least one layer of light-emitting material formed over the first transparent extensive electrode; and
a second reflective electrode formed over the at least one layer of light-emitting material;
forming a low-index layer between the first transparent extensive electrode and the one-or-more thin-film transistors, the low-index layer having an optical index lower than that of the layer of light-emitting material; and
forming a light-scattering layer between the low-index layer and the second reflective electrode, or formed as part of the second reflective electrode.

20. The method of claim 19, wherein the light-emitting layer comprises a layer of inorganic light-emitting particles.
